(19) United States
(12) Patent Application Publication
(10) Pub. No.: US 2025/0096035 A1
(43) Pub. Date: Mar. 20, 2025

(54) FILM-ON-INSULATOR SUBSTRATE INCLUDING A PRE-NOTCHED FILM AND METHODS OF FORMING THE SAME

(71) Applicant: Taiwan Semiconductor Manufacturing Company Limited, Hsinchu (TW)

(72) Inventors: Chen-Chiang Yu, Taoyuan City (TW); Tsung-Fu Tsai, Changhua City (TW); Szu-Wei Lu, Hsinchu City (TW); Jih-Churng Twu, Hsinchu (TW); Chung-Shi Liu, Hsinchu City (TW); Chen-Hua Yu, Hsinchu City (TW)

(21) Appl. No.: 18/470,557

(22) Filed: Sep. 20, 2023

(51) Int. Cl. H01L 21/762; H01L 23/00

(52) U.S. Cl. CPC H01L 21/76254; H01L 24/83; H01L 2224/83896

(57) ABSTRACT

A composite wafer may be provided by: forming a layer stack including a carrier layer, an ion implantation layer, and a transfer material layer by implanting ions into a donor wafer; forming intersecting trenches through the transfer material layer, the ion implantation layer, and an upper portion of the carrier layer; attaching the layer stack to an acceptor wafer including a stack of a handle substrate and a first dielectric oxide layer by bonding the layer stack to the first dielectric oxide layer; and cleaving the layer stack at the ion implantation layer, whereby a composite wafer including the acceptor wafer and patterned portions of the transfer material layer is formed.

### BACKGROUND

A film transfer process may be used to provide a film-on-insulator substrate. The film transfer process may include bonding a donor wafer and an acceptor wafer. The donor wafer contains a thin film that is cleaved off a bulk wafer portion after wafer bonding. However, bonding two materials with a coefficient of thermal expansion mismatch may lead to cracking in the bonded wafer during the post-bonding anneal process. Consequently, the post-bond anneal temperature may be restricted due to the mismatch, which limits the bonding strength between the transferred film and the insulator layer in the film-on-insulator substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1G are sequential vertical cross-sectional views of a first embodiment structure during formation of a composite wafer according to an embodiment of the present disclosure.

FIG. 1H is a top-down view of the composite wafer of FIG. 1G.

FIGS. 2A-2C are sequential vertical cross-sectional views of a second embodiment structure during formation of a composite wafer according to an embodiment of the present disclosure.

FIGS. 3A-3G are sequential vertical cross-sectional views of a third embodiment structure during formation of a composite wafer according to an embodiment of the present disclosure.

FIGS. 4A-4C are sequential vertical cross-sectional views of a fourth embodiment structure during formation of a composite wafer according to an embodiment of the present disclosure.

FIGS. 5A, 5B, and 5D are sequential vertical cross-sectional views of a fifth embodiment structure during formation of a composite wafer according to an embodiment of the present disclosure. FIG. 5C is top-down view of the fifth structure of FIG. 5B. FIG. 5E is a top-down view of the composite wafer of FIG. 5D.

FIGS. 6A, 6C, and 6D are sequential vertical cross-sectional views of a sixth embodiment structure during formation of a composite wafer according to an embodiment of the present disclosure. FIG. 6B is a top-down view of the donor wafer of FIG. 6A. FIG. 6E is a top-down view of the composite wafer of FIG. 6D.

FIGS. 7A, 7C, and 7D are sequential vertical cross-sectional views of a seventh embodiment structure during formation of a composite wafer according to an embodiment of the present disclosure. FIG. 7B is a top-down view of the donor wafer of FIG. 7A. FIG. 7E is a top-down view of the composite wafer of FIG. 7D.

FIG. 8 is a first flowchart illustrating steps for forming a composite wafer according to an embodiment of the present disclosure.

FIG. 9 is a second flowchart illustrating steps for forming a composite wafer according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein are directed to composite wafers including transferred material plates and methods for forming the same. A donor wafer including a transfer material layer may be provided. The transfer material layer may be patterned into an array of transfer material plates by forming intersecting trenches. The lateral dimensions of the transfer material plates may be reduced relative to the lateral dimensions of the transfer material layer. The transfer material plates may be transferred to an acceptor wafer to form a composite wafer including a plurality of transfer material plates, a dielectric oxide layer, and a handle substrate. The dielectric oxide layer may be directly bonded to the plurality of transfer material plates. Alternatively, dielectric oxide plates may be used as intermediate structures between the dielectric oxide layer and the plurality of transfer material plates. Reduction of the lateral dimensions of the transfer material plate may reduce the risk of cracking at bonding interfaces during the bonding process that is used to attach the plurality of transfer material plates to the dielectric oxide layer. Thus, a material having a large mismatch relative to the material of the handle substrate may be used for the transfer material plates without risking cracking during a wafer bonding process. Various aspects of embodiments of the present disclosure are now described with reference to accompanying figures.

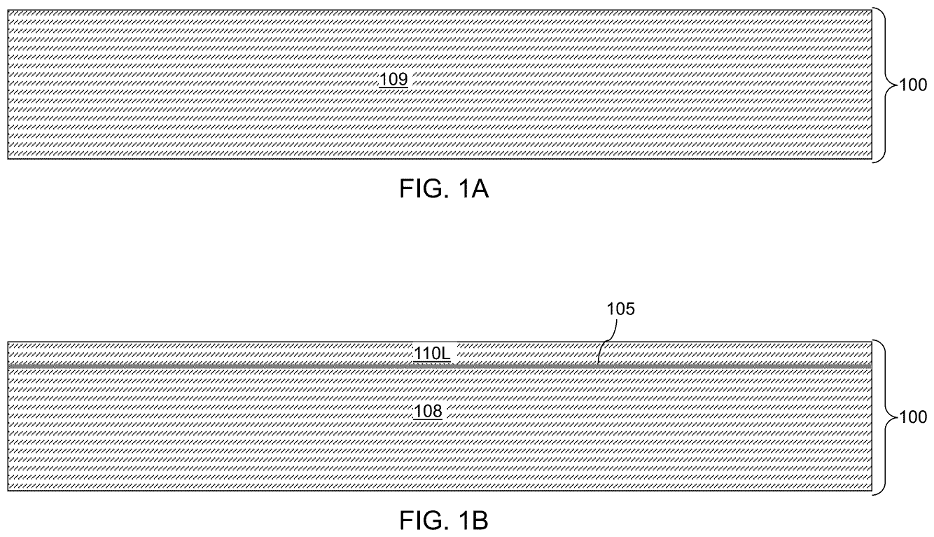

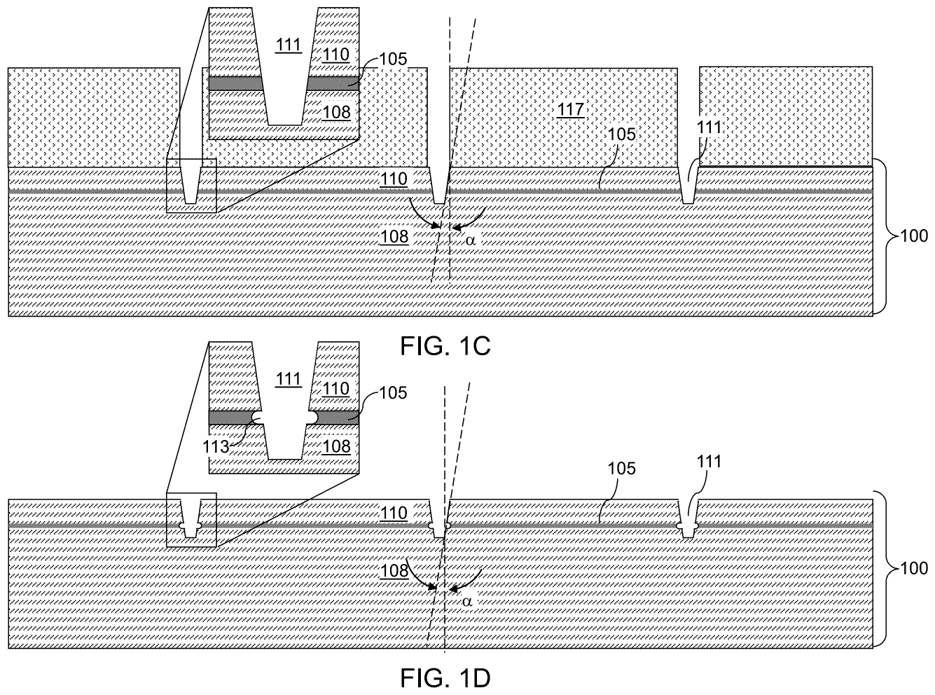

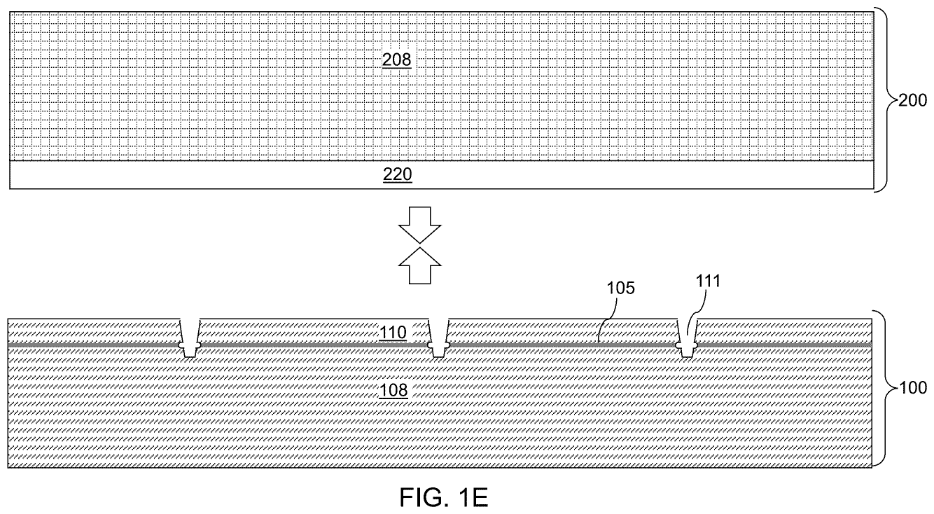

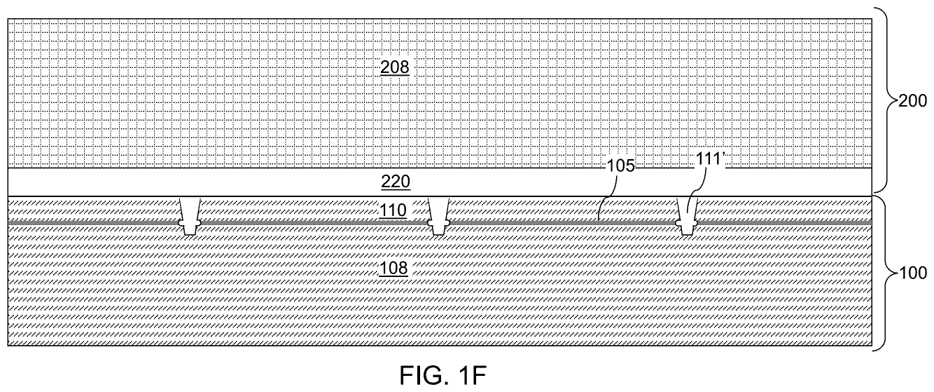

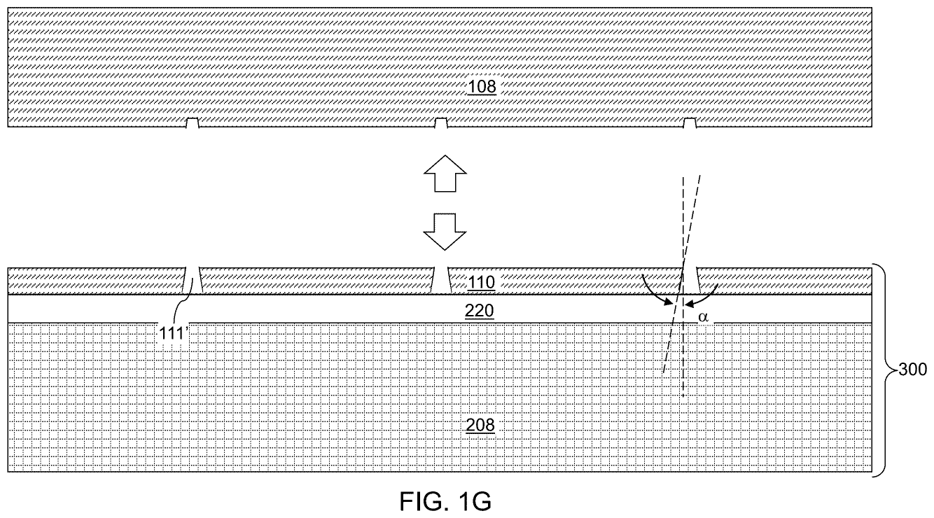

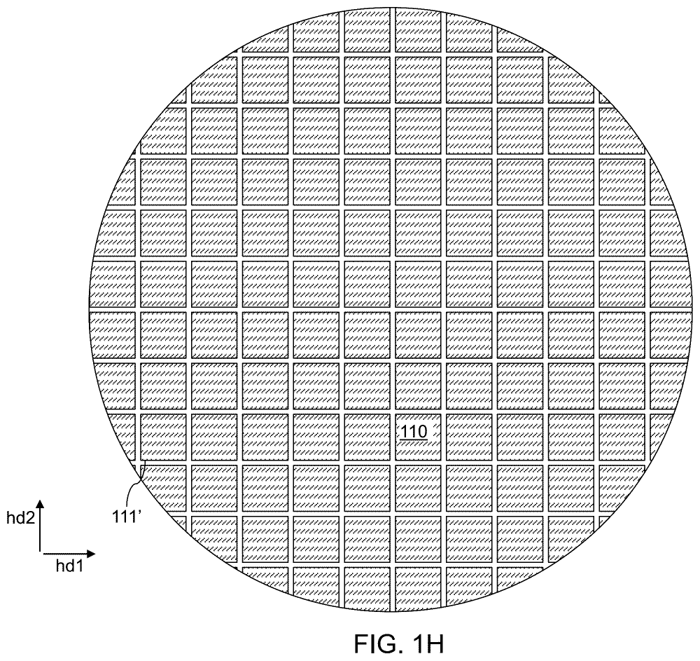

FIGS. 1A-1G are sequential vertical cross-sectional views of a first embodiment structure during formation of a composite wafer 300 according to an embodiment of the present disclosure.

Referring to FIG. 1A, the first embodiment structure may comprise a donor wafer 100 including a donor material layer 109. The donor wafer 100 may have a lateral dimension (such as a diameter) in a range from 50 mm to 450 mm, although lesser and greater lateral dimensions may also be used. The donor material layer 109 may have a thickness that provides sufficient mechanical strength to the donor wafer 100. For example, the donor material layer 109 may have a thickness in a range from 100 microns to 2,000 microns, such as from 200 microns to 1,000 microns, although lesser and greater thicknesses may also be used. The donor material layer 109 comprises, and/or consists essentially of, a material to be transferred to a top portion of an acceptor wafer to provide a composite wafer. As such, the material of the donor material layer 109 is herein referred to as a transfer material.

The transfer material may comprise a semiconductor material, an insulating material, or a conductive material. Embodiments of the present disclosure may be used with any transfer material that may be directly bonded to a dielectric material in an acceptor wafer, or in combination with another dielectric material that may be deposited on the transfer material and may be subsequently bonded to the dielectric material in the acceptor wafer. Generally, the transfer material may be a high-quality high-purity material, and may comprise a single crystalline material. According to an aspect of the present disclosure, the transfer material may comprise a material having a large mismatch in coefficients of thermal expansion relative to the material of a handle substrate in the acceptor wafer to be subsequently used.

In an illustrative example, the donor material layer 109 in the donor wafer 100 may comprise, and/or may consist essentially of, a semiconductor material such as silicon, germanium, a silicon-germanium alloy, or a compound semiconductor material such as a semiconducting metal oxide material. In one embodiment, the donor material layer 109 in the donor wafer 100 may comprise, and/or may consist essentially of, a single crystalline semiconductor material, which may comprise single crystalline silicon, single crystalline germanium, a single crystalline silicon-germanium alloy, or a single crystalline compound semiconductor material. In one embodiment, the donor material layer 109 in the donor wafer 100 may comprise, and/or may consist essentially of, a single crystalline compound semiconductor material such as single crystalline lithium niobate (LiNbO₃), single crystalline lithium tantalate (LiTaO₃), single crystalline zinc oxide, single crystalline titanium oxide, single crystalline indium tin oxide, single crystalline gallium oxide, single crystalline tin oxide, single crystalline tungsten trioxide, etc. In one embodiment, the donor material layer 109 in the donor wafer 100 may comprise, and/or may consist essentially of, single crystalline lithium niobate or single crystalline lithium tantalate.

Referring to FIG. 1B, an ion implantation process may be performed to implant ions of light elements such as hydrogen and/or helium into the donor wafer 100. The kinetic energy of the ions implanted into the donor wafer 100 may be selected depending on the target ion implantation depth, and may be in a range from 50 keV to 500 keV, such as from 100 keV to 400 keV, although lesser and greater kinetic energies may also be used. The implantation depth may be in a range from 0.2 microns to 1.5 microns, such as from 0.4 microns to 1.2 microns, although lesser and greater implantation depths may also be used. The dose of the ion implantation process may be selected to provide subsequent cleaving of the donor wafer 100 at the layer formed by the ion implantation process, which is herein referred to as an ion implantation layer 105. In an illustrative example, the dose of the ion implantation process may be in a range from 1.0×10¹⁶ ions/cm² to 5.0×10¹⁷ ions/cm², although lesser and greater doses may also be used. An upper portion of the donor material layer 109 that overlies the ion implantation layer 105 is herein referred to as a transfer material layer 110L, which comprises a material to be transferred to an acceptor wafer. A lower portion of the donor material layer 109 that underlies the ion implantation layer 105 is herein referred to as a carrier layer 108, which is used to carry the transfer material layer 110L until separation of the carrier layer 108 from the acceptor wafer. Generally, a layer stack (110L, 105, 108) comprising a carrier layer 108, an ion implantation layer 105, and a transfer material layer 110L may be formed by implanting ions into a donor wafer 100.

Referring to FIG. 1C and 1H, a patterned etch mask layer 117 including intersecting laterally-extending openings may be formed over the transfer material layer 110L. For example, the patterned etch mask layer 117 may comprise a patterned photoresist layer. In this embodiment, a blanket (un-patterned) photoresist layer may be applied over the transfer material layer 110L, and may be lithographically patterned to form two intersecting sets of line-shaped openings. A set of first line-shaped openings may laterally extend along a first horizontal direction hd1 with a uniform width, and a set of second line-shaped openings may laterally extend along a second horizontal direction with the uniform width. The second horizontal direction hd2 may be perpendicular to the first horizontal direction hd1. The pattern of the first line-shaped openings may be periodic along the second horizontal direction hd2, and the pattern of the second line-shaped openings may be periodic along the first horizontal direction hd1.

In one embodiment, each patterned portion of the patterned etch mask layer 117 may have a rectangular horizontal cross-sectional shape. According to an aspect of the present disclosure, the lateral dimensions (such as a length and a width) of each patterned portion of the patterned etch mask layer 117 may be selected to prevent formation of cracks in the material of the transfer material layer 110L during a bonding process that bonds the material of the transfer material layer 110L to an acceptor wafer. For example, the lateral dimensions (such as a length and a width) of each patterned portion of the patterned etch mask layer 117 may be in a range from 5 mm to 100 mm, such as from 10 nm to 50 mm, although lesser and greater lateral dimensions may also be used. The width of each line-shaped opening in the patterned etch mask layer 117 may be in a range from 30 microns to 300 microns, such as from 60 microns to 150 microns, although lesser and greater widths may also be used.

An anisotropic etch process may be performed to transfer the pattern of the line-shaped openings in the patterned etch mask layer 117 through the transfer material layer 110L and the ion implantation layer 105 and into an upper portion of the carrier layer 108. The chemistry of the anisotropic etch process may be selected based on the transfer material, i.e., the material of the transfer material layer 110L and the carrier layer 108. In an illustrative example, in embodiments in which the transfer material comprises single crystalline lithium niobate or single crystalline lithium tantalate, the anisotropic etch process may have an etch chemistry that uses a combination of carbon tetrafluoride and oxygen. In embodiments in which the transfer material comprises single crystalline lithium niobate or single crystalline lithium tantalate, the anisotropic etch process may have an etch chemistry that uses a combination of carbon tetrafluoride and hydrogen or a combination of sulfur hexafluoride and oxygen. Generally, the transfer material layer 110L may be patterned into transfer material plates 110 by the anisotropic etch process.

The anisotropic etch process forms intersecting trenches 111 through the transfer material layer 110L, the ion implantation layer 105, and an upper portion of the carrier layer 108. In one embodiment, the sidewalls of the intersecting trenches 111 may be formed with a taper angle α with respect to a vertical direction. The taper angle α may be in a range from 0.1 degree to 10 degrees, such as from 0.3 degrees to 5 degrees, although lesser and greater values may also be used for a taper angle α. The width of each of the intersecting trenches 111 decreases with a vertical distance downward from a horizontal plane including top surfaces of the patterned portions of the transfer material layer 110L (i.e., the transfer material plates 110).

Referring to FIG. 1D, an isotropic etch process may be performed to etch the material of the ion implantation layer 105 selective to the transfer material, i.e., the material of the carrier layer 108 and the transfer material layer 110L. For example, a wet etch process using a mixture of hydrofluoric acid and nitric acid may be performed to selectively etch physically expose surface portions of the ion implantation layer 105. The lateral recess distance of the isotropic etch process may be in a range from 10 nm to 1,000 nm, such as from 30 nm to 300 nm, although lesser and greater lateral recess distances may also be used. Lateral divots 113 may be formed around the intersecting trenches 111 by laterally recessing the ion implantation layer 105 selective to the material of the carrier layer 108 and the transfer material layer 110L. The height of each of the lateral divots 113 may be the same as the thickness of the ion implantation layer 105. The patterned etch mask layer 117 may be subsequently removed, for example, by ashing or dissolution.

Referring to FIG. 1E, an acceptor wafer 200 including a handle substrate 208 and a first dielectric oxide layer is provided. The first dielectric oxide layer is herein referred to as an acceptor-side dielectric oxide layer 220. The handle substrate 208 may comprise any material, which may comprise a semiconductor material such as silicon, an insulating material, or a conductive material such as a metallic material. The thickness of the handle substrate 208 may be in a range from 300 microns to 2,000 microns, such as from 500 microns to 1,000 microns, although lesser and greater thicknesses may also be used.

The acceptor-side dielectric oxide layer 220 comprises a dielectric material layer that is conducive to bonding with the transfer material of the transfer material plates 110. For example, the acceptor-side dielectric oxide layer 220 may comprise undoped silicate glass, a doped silicate glass, or thermally-grown silicon oxide, i.e., silicon oxide formed by oxidation of silicon. The thickness of the acceptor-side dielectric oxide layer 220 may be in a range from 50 nm to 500 nm, although lesser and greater thicknesses may also be used. In an illustrative example, the handle substrate 208 may comprise single crystalline silicon or polycrystalline silicon, and the acceptor-side dielectric oxide layer 220 may comprise thermally-grown silicon oxide which is a stoichiometric silicon oxide that is free of carbon or hydrogen. Alternatively, the acceptor-side dielectric oxide layer 220 may comprise undoped silicate glass or a doped silicate glass.

The acceptor wafer 200 may have the same lateral dimension as the donor wafer 100, or may have a greater lateral dimension than the donor wafer 100. The donor wafer 100 may be oriented such that the two-dimensional array of transfer material plates 110 faces the acceptor-side dielectric oxide layer 220. Subsequently, the donor wafer 100 may be brought into contact with the acceptor wafer 200 such that the two-dimensional array of transfer material plates 110 contacts a physically exposed planar surface of the acceptor-side dielectric oxide layer 220.

Referring to FIG. 1F, the layer stack (110, 105, 108) of the donor wafer 100 may be attached to the acceptor wafer 200 by bonding the layer stack (110, 105, 108) to the first dielectric oxide layer (such as the acceptor-side dielectric oxide layer 220) of the acceptor wafer 200. Specifically, the first dielectric oxide layer (such as an acceptor-side dielectric oxide layer 220) may be bonded to the two-dimensional array of transfer material plates 110, which comprises patterned portions of the transfer material layer 110L. In an illustrative example, the bonding process may comprise a first thermal anneal process at an elevated temperature in a range from 130 degrees Celsius to 250 degrees Celsius. The duration of the first thermal anneal process may be in a range from 2 hours to 48 hours such as from 4 hours to 24 hours, although lesser and greater durations may also be used.

Intersecting laterally-extending channels 111′, i.e., laterally-extending channels that intersect with one another, are formed upon attaching the acceptor wafer 200 to the transfer material plates 110. Surface segments of the first dielectric oxide layer (such as an acceptor-side dielectric oxide layer 220) may be exposed to the intersecting laterally-extending channels 111′. A bonded assembly of the donor wafer 100 and the acceptor wafer 200 may be formed. The intersecting laterally-extending channels 111′ are interconnected with one another, and laterally extend to a peripheral sidewall of the donor wafer 100.

Referring to FIGS. 1F and 1G, the layer stack (110, 105, 108) may be cleaved at the ion implantation layer 105. The cleaving of the layer stack (110, 105, 108) may be affected by performing a second thermal anneal process, which may be a continuation of the first thermal anneal process at a higher temperature. For example, the second thermal anneal process may be performed at an elevated temperature in a range from 230 degrees Celsius to 400 degrees Celsius, such as from 250 degrees Celsius to 350 degrees Celsius. The duration of the second thermal anneal process may be in a range from 10 minutes to 12 hours, such as from 30 minutes to 4 hours, although shorter and longer durations may also be used.

The carrier layer 108 may be detached from the assembly of the handle substrate 208, the first dielectric oxide layer (such as the acceptor-side dielectric oxide layer 220), and a two-dimensional array of transfer material plates 110, which is hereafter referred to as a composite wafer 300. Thus, the composite wafer 300 includes the acceptor wafer 200 and the transfer material plates 110 (which comprise patterned portions of the transfer material layer 110L). A first dielectric oxide layer (such as an acceptor-side dielectric oxide layer 220) may be located on a top surface of a handle substrate 208, and a two-dimensional array of transfer material plates 110 may be attached to the first dielectric oxide layer (such as the acceptor-side dielectric oxide layer 220). The two-dimensional array of transfer material plates 110 may be laterally spaced from one another by the intersecting channels 111′. The intersecting channels 111′ may vertically extend from planar top surfaces of the transfer material plates 110 to a top surface of the first dielectric oxide layer (such as the acceptor-side dielectric oxide layer 220). In one embodiment, the height of each intersecting channel 111′ may be the same as the thickness of the transfer material plates 110.

In one embodiment, the sidewalls of the transfer material plates 110 may have a reverse-tapered profile such that the lateral extent of each transfer material plate 110 increases with a vertical distance from the first dielectric oxide layer (such as the acceptor-side dielectric oxide layer 220). The sidewalls of the transfer material plates 110 may have a taper angle α. In one embodiment, each of the intersecting channels 111′ may have a variable lateral width that decreases with a vertical distance upward from the top surface of the first dielectric oxide layer (such as the acceptor-side dielectric oxide layer 220). In one embodiment, the two-dimensional array of transfer material plates 110 may be in contact with the top surface of the first dielectric oxide layer (such as the acceptor-side dielectric oxide layer 220).

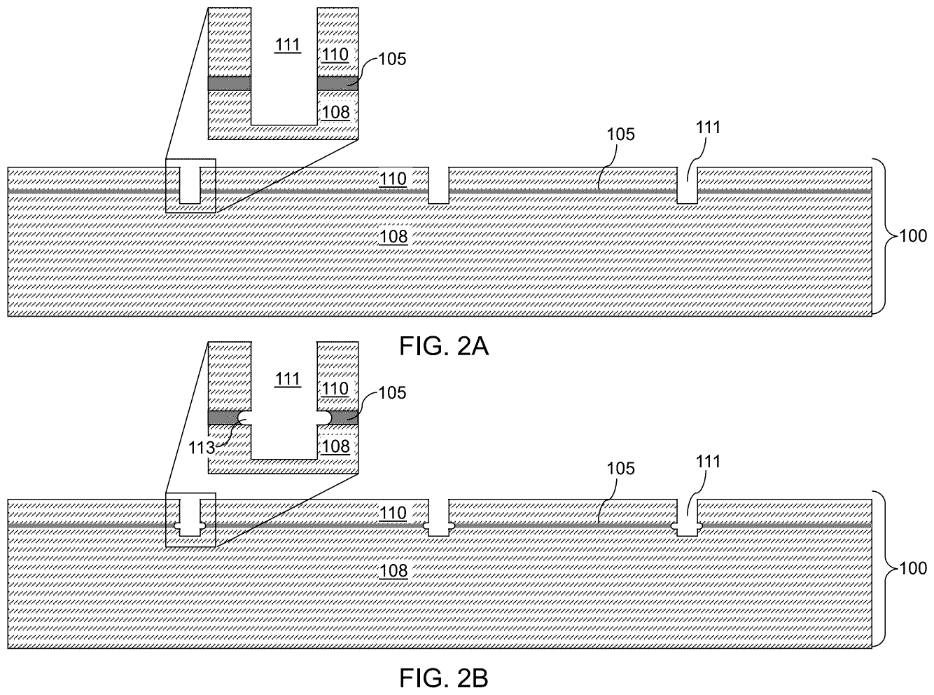

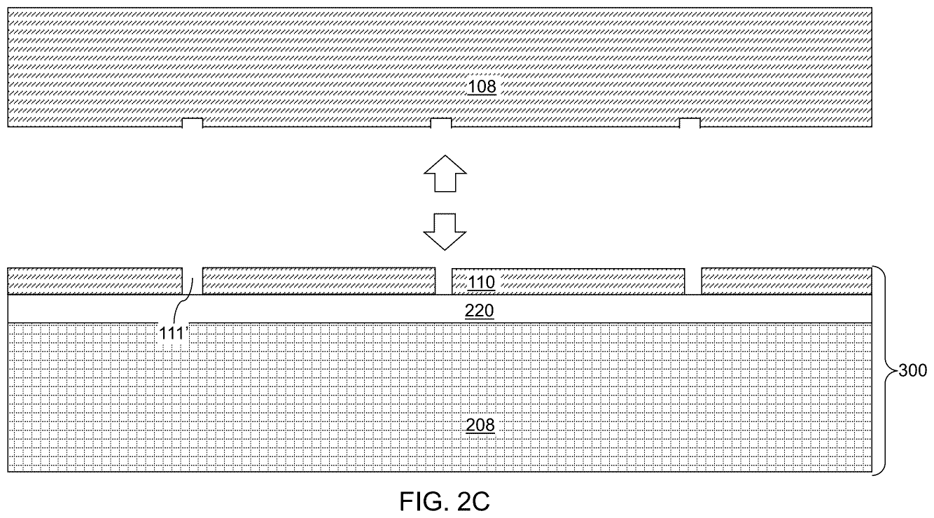

FIGS. 2A-2C are sequential vertical cross-sectional views of a second embodiment structure during formation of a composite wafer 300 according to an embodiment of the present disclosure.

Referring to FIG. 2A, a second embodiment structure may be derived from the first embodiment structure illustrated in FIG. 1B by forming the intersecting trenches 111 using mechanical means. For example, the intersecting trenches 111 may be formed by mechanically cutting the transfer material layer 110L, the ion implantation layer 105, and the upper portion of the carrier layer 108. In this embodiment, a dicing saw may be used, and the height of the dicing blade may be set such that the depth of the cut is greater than the vertical distance from the horizontal plane including the top surface of the transfer material layer 110L to the top surface of the carrier layer 108. The intersecting trenches 111 in the donor wafer 100 of FIG. 2A may have the same pattern as the intersecting trenches 111 in the donor wafer 100 of FIG. 1C. The width of each trench selected from the intersecting trenches 111 may be in a range from 30 microns to 300 microns, such as from 50 microns to 150 microns, although lesser and greater widths may also be used. Each trench selected from the intersecting trenches 111 may be laterally bounded by a pair of vertical sidewalls of the transfer material plates 110.

Referring to FIG. 2B, the processing steps of FIG. 1D may be performed to form lateral divots 113 around the intersecting trenches 111. The isotropic etch process may etch the material of the ion implantation layer 105 selective to the transfer material, i.e., the material of the carrier layer 108 and the transfer material layer 110L.

Referring to FIG. 2C, the processing steps described with reference to FIGS. 1E, 1F, and 1G may be performed to form a composite wafer 300. In this embodiment, each of the transfer material plates 110 in the composite wafer 300 may comprise a respective set of four vertical sidewalls that are adjoined at four vertically-extending edges.

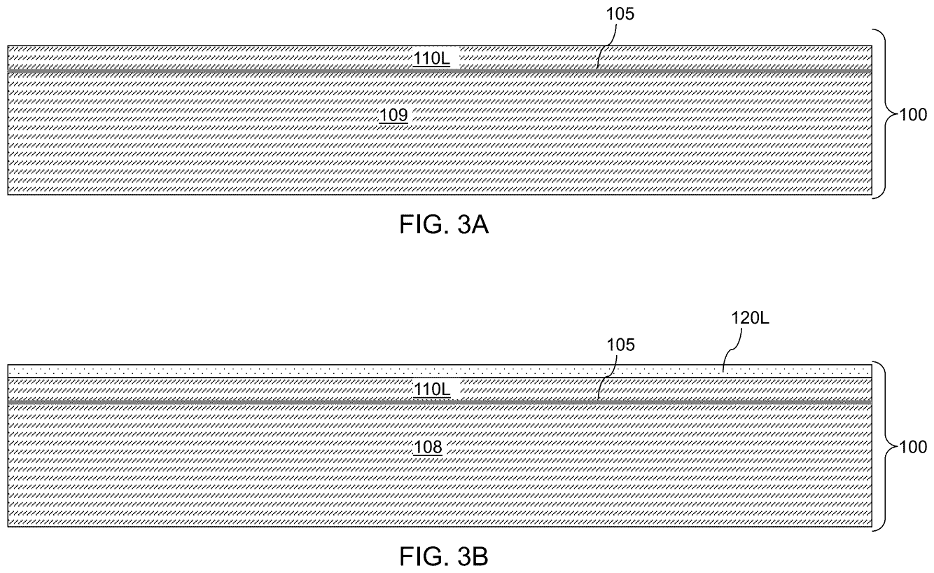

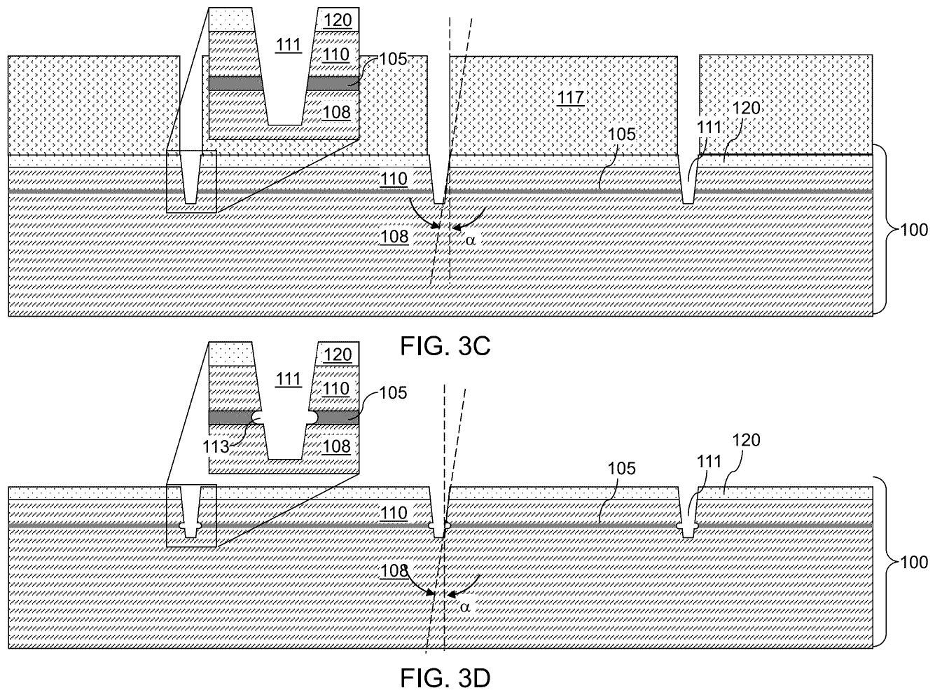

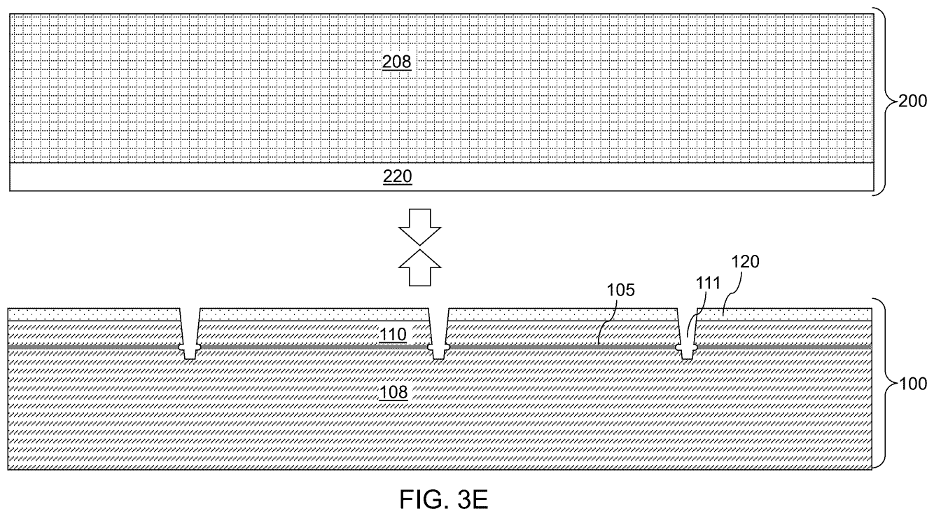

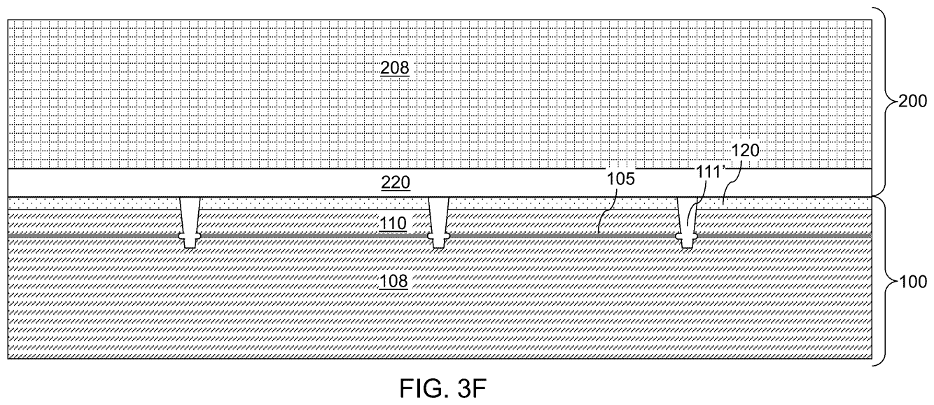

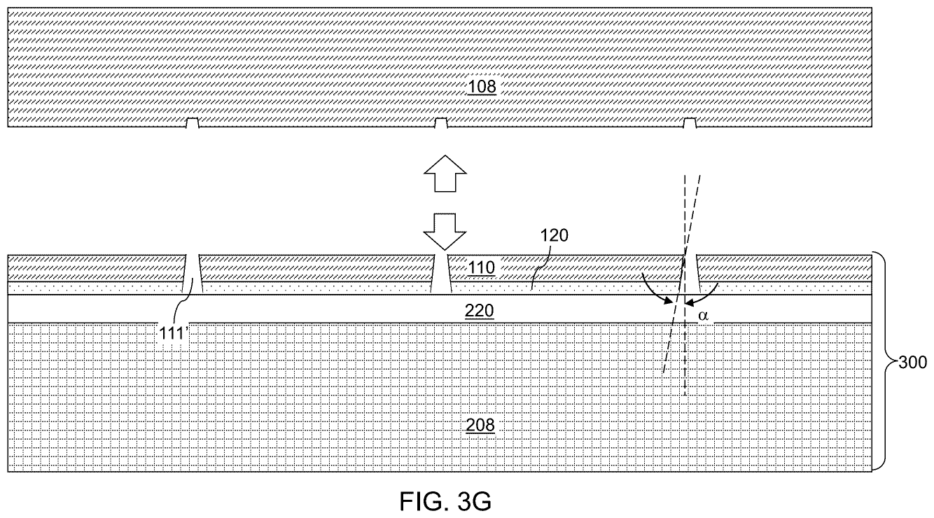

FIGS. 3A-3G are sequential vertical cross-sectional views of a third embodiment structure during formation of a composite wafer 300 according to an embodiment of the present disclosure.

Referring to FIG. 3A, a donor wafer 100 for the third exemplary structure is illustrated, which may be the same as the donor wafer 100 provided after the processing steps described with reference to FIG. 1B. The donor material layer 109 is converted into a combination of a transfer material layer 110L, an ion implantation layer 105, and a carrier layer 108.

Referring to FIG. 3B, a dielectric oxide layer may be formed on a top surface of the transfer material layer 110L. The dielectric oxide layer that is formed on the top surface of the transfer material layer 110L is herein referred to as a donor-side dielectric oxide layer 120L, and may be referred to as a first dielectric oxide layer or as a second dielectric oxide layer in the claims. Generally, the donor-side dielectric oxide layer 120L may be formed after, or prior to, implanting the ions into the donor wafer 100 that forms the ion implantation layer 105.

The donor-side dielectric oxide layer 120L comprises a dielectric oxide material that is conductive to bonding with another dielectric oxide material. For example, the donor-side dielectric oxide layer 120L may comprise, and/or may consist essentially of, undoped silicate glass or a doped silicate glass. The donor-side dielectric oxide layer 120L may be formed by chemical vapor deposition or physical vapor deposition. The thickness of the donor-side dielectric oxide layer 120L may be in a range from 50 nm to 500 nm, although lesser and greater thicknesses may also be used. Upon incorporation of the donor-side dielectric oxide layer 120L, the donor wafer 100 comprises a layer stack (120L, 110L, 105, 108) including the donor-side dielectric oxide layer 120L, the transfer material layer 110L, the ion implantation layer 105, and the carrier layer 108.

Referring to FIG. 3C, the processing steps described with reference to FIG. 1C may be performed with the donor-side dielectric oxide layer 120L in the donor wafer 100. The anisotropic etch process may be modified to add an anisotropic etch step that etches the material of the donor-side dielectric oxide layer 120L prior to etching the material of the transfer material layer 110L. Intersecting trenches 111 are formed through the donor-side dielectric oxide layer 120L, the transfer material layer 110L, the ion implantation layer 105, and an upper portion of the carrier layer 108. The donor-side dielectric oxide layer 120L is patterned into dielectric oxide plates 120 during the anisotropic etch process, i.e., during formation of the intersecting trenches 111. As discussed above, the sidewalls of the intersecting trenches 111 may be formed with a taper angle α relative to the vertical direction. In one embodiment, the tapered sidewalls of the intersecting trenches 111 may comprise physically exposed sidewalls of the dielectric oxide plates 120 having the taper angle α.

Referring to FIG. 3D, the processing steps described with reference to FIG. 1D may be performed to form lateral divots 113 around the intersecting trenches 111. Specifically, the ion implantation layer 105 may be laterally recessed selective to the material of the carrier layer 108 and the transfer material layer 110L and selective to the material of the dielectric oxide plates 120. The height of each of the lateral divots 113 may be the same as the thickness of the ion implantation layer 105. The patterned etch mask layer 117 may be subsequently removed, for example, by ashing or dissolution.

Referring to FIG. 3E, the processing steps described with reference to FIG. 1E may be performed to provide an acceptor wafer 200 including a handle substrate 208 and an acceptor-side dielectric oxide layer 220. The acceptor-side dielectric oxide layer 220 may be referred to as a first dielectric oxide layer or as a second dielectric oxide layer in the claims. The donor wafer 100 may be oriented such that the two-dimensional array of transfer material plates 110 faces the acceptor-side dielectric oxide layer 220. Subsequently, the donor wafer 100 may be brought into contact with the acceptor wafer 200 such that a two-dimensional array of dielectric oxide plates 120 contacts a physically exposed planar surface of the acceptor-side dielectric oxide layer 220.

Referring to FIG. 3F, the layer stack (120, 110, 105, 108) of the donor wafer 100 may be attached to the acceptor wafer 200 by bonding the layer stack (120, 110, 105, 108) to a first dielectric oxide layer (such as the acceptor-side dielectric oxide layer 220) of the acceptor wafer 200. Specifically, the first dielectric oxide layer (such as an acceptor-side dielectric oxide layer 220) is bonded to the two-dimensional array of dielectric oxide plates 120, which comprises patterned portions of a second dielectric oxide layer (such as a donor-side dielectric oxide layer 120L). In an illustrative example, the bonding process may comprise a first thermal anneal process at an elevated temperature in a range from 130 degrees Celsius to 250 degrees Celsius. The duration of the first thermal anneal process may be in a range from 2 hours to 48 hours such as from 4 hours to 24 hours, although lesser and greater durations may also be used. The first dielectric oxide layer (such as an acceptor-side dielectric oxide layer 220) is bonded to the dielectric oxide plates 120 by dielectric-to-dielectric bonding. If the first dielectric oxide layer and the dielectric oxide plates 120 comprise silicon oxide materials, the first dielectric oxide layer and the dielectric oxide plates 120 may be bonded to each other by silicon oxide-to-silicon oxide bonding.

Intersecting laterally-extending channels 111′, i.e., laterally-extending channels that intersect with one another, are formed upon attaching the acceptor wafer 200 to the transfer material plates 110. Surface segments of the first dielectric oxide layer (such as an acceptor-side dielectric oxide layer 220) may be exposed to the intersecting laterally-extending channels 111′. A bonded assembly of the donor wafer 100 and the acceptor wafer 200 may be formed. The intersecting laterally-extending channels 111′ are interconnected with one another, and laterally extend to a peripheral sidewall of the donor wafer 100.

Referring to FIG. 3G, the layer stack (120, 110, 105, 108) may be cleaved at the ion implantation layer 105. The cleaving of the layer stack (120, 110, 105, 108) may be effected by performing a second thermal anneal process, which may be a continuation of the first thermal anneal process at a higher temperature. For example, the second thermal anneal process may be performed at an elevated temperature in a range from 230 degrees Celsius to 400 degrees Celsius, such as from 250 degrees Celsius to 350 degrees Celsius. The duration of the second thermal anneal process may be in a range from 10 minutes to 12 hours, such as from 30 minutes to 4 hours, although shorter and longer durations may also be used.

The carrier layer 108 may be detached from the assembly of the handle substrate 208, the first dielectric oxide layer (such as the acceptor-side dielectric oxide layer 220), a two-dimensional array of dielectric oxide plates 120 (which comprise patterned portions of a second dielectric oxide layer such as a donor-side dielectric oxide layer), and a two-dimensional array of transfer material plates 110. The assembly is hereafter referred to as a composite wafer 300. Thus, the composite wafer 300 includes the acceptor wafer 200 and the transfer material plates 110 (which comprise patterned portions of the transfer material layer 110L). A first dielectric oxide layer (such as an acceptor-side dielectric oxide layer 220) may be located on a top surface of a handle substrate 208, and a two-dimensional array of transfer material plates 110 may be attached to the first dielectric oxide layer (such as the acceptor-side dielectric oxide layer 220) through a two-dimensional array of dielectric oxide plates 120 (which comprise patterned portions of a second dielectric oxide layer such as a donor-side dielectric oxide layer). The two-dimensional array of transfer material plates 110 may be laterally spaced from one another by the intersecting channels 111′. The intersecting channels 111′ may vertically extend from planar top surfaces of the transfer material plates 110 to a top surface of the first dielectric oxide layer (such as the acceptor-side dielectric oxide layer 220). In one embodiment, the height of each intersecting channel 111′ may be the same as the sum of the thickness of the transfer material plates 110 and the thickness of the dielectric oxide plates 120.

In one embodiment, the sidewalls of the transfer material plates 110 may have a reverse-tapered profile such that the lateral extent of each transfer material plate 110 increases with a vertical distance from the first dielectric oxide layer (such as the acceptor-side dielectric oxide layer 220). The sidewalls of the transfer material plates 110 may have a taper angle α. In one embodiment, the sidewalls of the dielectric oxide plates 120 may have a reverse-tapered profile such that the lateral extent of each dielectric oxide plate 120 increases with a vertical distance from the first dielectric oxide layer (such as the acceptor-side dielectric oxide layer 220). The sidewalls of the dielectric oxide plates 120 may have the taper angle α. In one embodiment, each of the intersecting channels 111′ may have a variable lateral width that decreases with a vertical distance upward from the top surface of the first dielectric oxide layer (such as the acceptor-side dielectric oxide layer 220).

In one embodiment, the two-dimensional array of transfer material plates 110 may be vertically spaced from the top surface of the first dielectric oxide layer (such as the acceptor-side dielectric oxide layer 220) by a two-dimensional array of dielectric oxide plates 120. In this embodiment, a two-dimensional array of dielectric oxide plates (such as dielectric oxide plates 120) may be interposed between the two-dimensional array of transfer material plates 110 and the first dielectric oxide layer (such as an acceptor-side dielectric oxide layer 220).

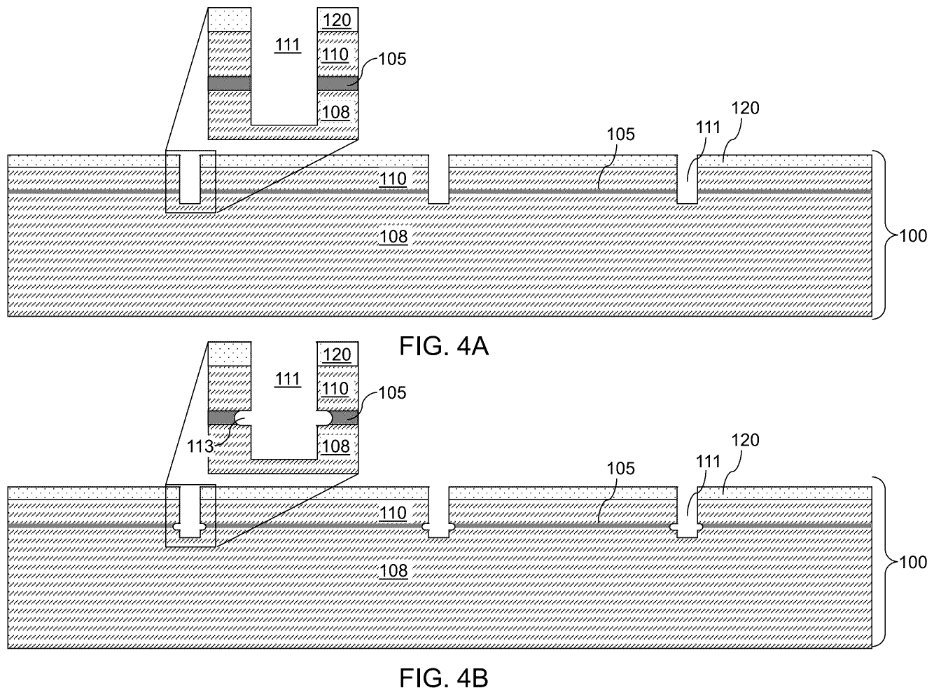

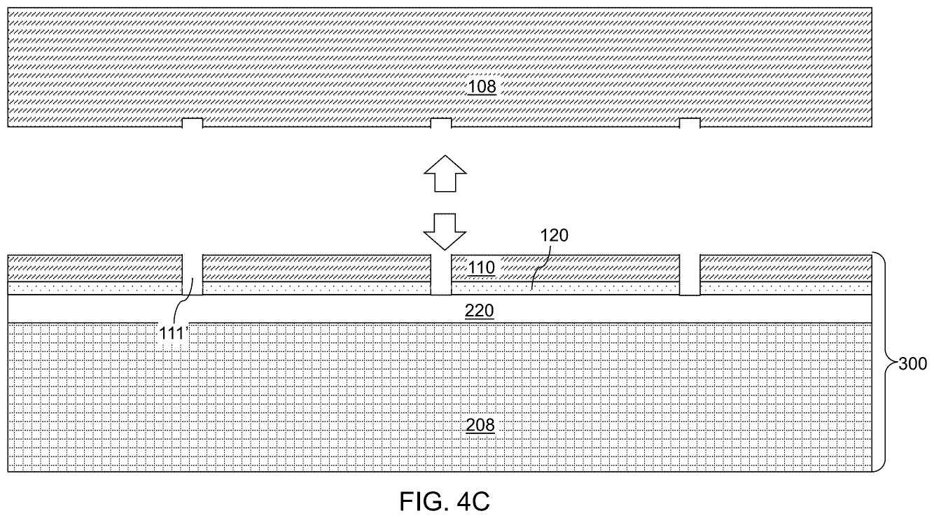

FIGS. 4A-4C are sequential vertical cross-sectional views of a fourth embodiment structure during formation of a composite wafer 300 according to an embodiment of the present disclosure.

Referring to FIG. 4A, a fourth embodiment structure may be derived from the third embodiment structure illustrated in FIG. 3B by forming the intersecting trenches 111 using mechanical means. For example, the intersecting trenches 111 may be formed by mechanically cutting the donor-side dielectric oxide layer 120L, the transfer material layer 110L, the ion implantation layer 105, and the upper portion of the carrier layer 108. In this embodiment, a dicing saw may be used, and the height of the dicing blade may be set such that the depth of the cut is greater than the vertical distance from the horizontal plane including the top surface of the transfer material layer 110L to the top surface of the carrier layer 108. The intersecting trenches 111 in the donor wafer 100 of FIG. 4A may have the same pattern as the intersecting trenches 111 in the donor wafer 100 of FIG. 3C. The width of each trench selected from the intersecting trenches 111 may be in a range from 30 microns to 300 microns, such as from 50 microns to 150 microns, although lesser and greater widths may also be used. Each trench selected from the intersecting trenches 111 may be laterally bounded by a pair of vertical sidewalls of the transfer material plates 110.

Referring to FIG. 4B, the processing steps of FIG. 3D may be performed to form lateral divots 113 around the intersecting trenches 111. The isotropic etch process may etch the material of the ion implantation layer 105 selective to the transfer material, i.e., the material of the carrier layer 108 and the transfer material layer 110L.

Referring to FIG. 4C, the processing steps described with reference to FIGS. 3E and 3F may be performed to form a composite wafer 300. In this embodiment, each of the transfer material plates 110 in the composite wafer 300 may comprise a respective set of four vertical sidewalls that are adjoined at four vertically-extending edges.

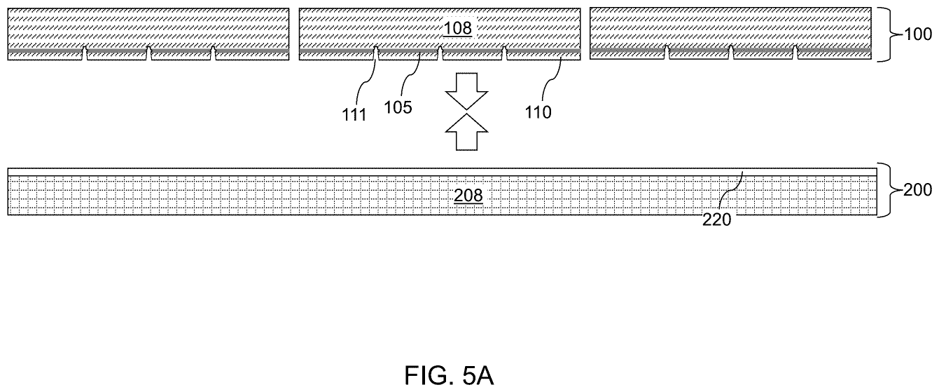

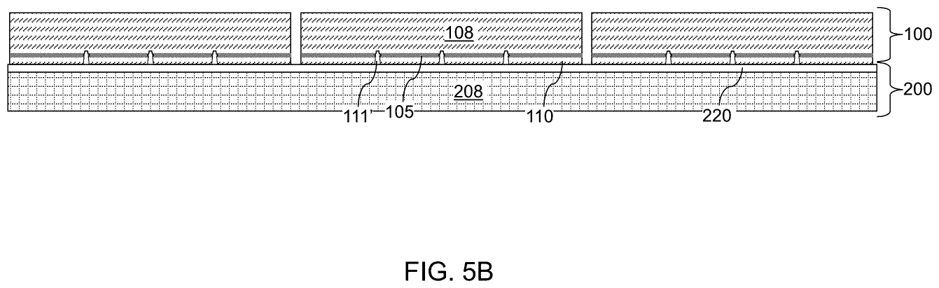

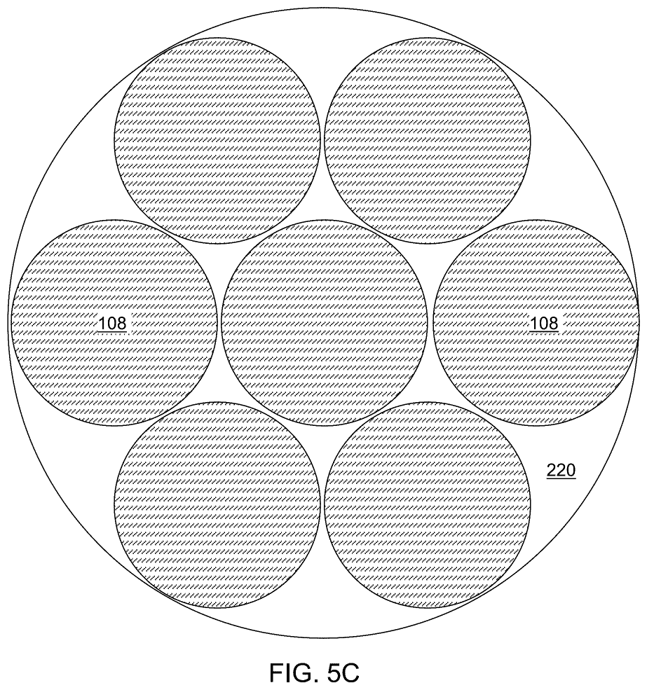

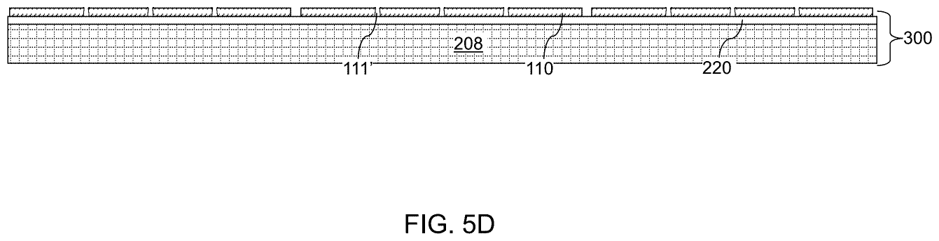

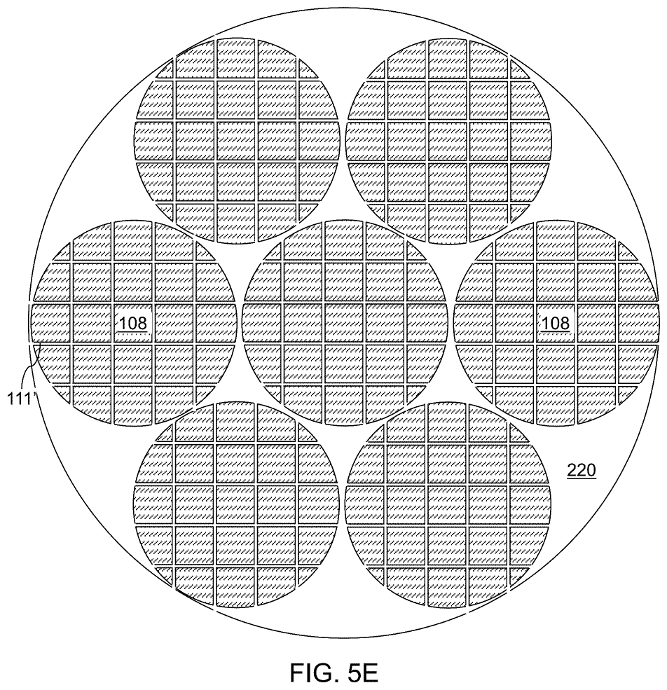

FIGS. 5A, 5B, and 5D are sequential vertical cross-sectional views of a fifth embodiment structure during formation of a composite wafer 300 according to an embodiment of the present disclosure. FIG. 5C is top-down view of the fifth exemplary structure of FIG. 5B. FIG. 5E is a top-down view of the composite wafer 300 of FIG. 5D.

Referring to FIG. 5A, a plurality of donor wafers 100 each including a respective layer stack (optional 120, 110, 105, 108) in any of the above-described embodiments may be provided. Thus, each donor wafer 100 may comprise a respective layer stack (optional 120L, 110L, 105, 108) that comprises a respective optional dielectric oxide layer (such as a donor-side dielectric oxide layer 120L), a transfer material layer 110L, a respective additional ion implantation layer 105, and a respective additional carrier layer 108. Intersecting trenches 111 through an upper portion of each of the at least one additional layer stack (optional 120L, 110L, 105, 108). Each patterned layer stack may comprise an optional two-dimensional array of dielectric oxide plates (not shown), a two-dimensional array of transfer material plates 110, an ion implantation layer 105, and a carrier layer 108.

In the fifth embodiment structure, the donor wafers 100 have a smaller area in a plan view (such as a top-down view) than the area of an acceptor wafer 200 in the plan view. In one embodiment, the area of the acceptor wafer 200 may be large enough to fit in two or more donor wafers 100. Each of the donor wafers 100 may be oriented such that the two-dimensional arrays of transfer material plates 110 face the acceptor-side dielectric oxide layer 220. Subsequently, the donor wafers 100 may be brought into contact with the acceptor wafer 200 such that the two-dimensional arrays of transfer material plates 110 contact a physically exposed planar surface of the acceptor-side dielectric oxide layer 220.

Referring to FIGS. 5B and 5C, the processing steps described with reference to FIG. 1F or the processing steps described with reference to FIG. 3F may be performed with a modification that each of the donor wafers 100 is pressed against the acceptor wafer 200 during the bonding process. Generally, each of the donor wafers 100 including a respective layer stack (optional 120, 110, 105, 108) may be attached to the acceptor wafer 200 by bonding each of the layer stacks (optional 120, 110, 105, 108) to the first dielectric oxide layer (such as an acceptor-side dielectric oxide layer 220) of the acceptor wafer 200.

The illustrated example corresponds to an embodiment in which a total of 7 donor wafers 100 are attached to an acceptor wafer 200. Generally, two or more donor wafers 100 may be attached to a same acceptor wafer 200 in the fifth exemplary structure. Further, while the present disclosure is described using an embodiment in which each of the donor wafers 100 has a circular shape in a plan view, the donor wafers 100 may generally have any two-dimensional shape having a closed periphery in a plan view. For example, the donor wafers 100 may have an elliptical shape, a polygonal shape, or any two-dimensional curvilinear shape having a closed periphery in a plan view. The size of the donor wafers 100 may be the same or different from one another.

Referring to FIGS. 5D and 5E, the processing steps described with reference to FIGS. 1G and 1H or the processing steps described with reference to FIG. 3G may be performed to cleave each of the layer stacks (optional 120, 110, 105, 108) at the respective additional ion implantation layer 105. A composite wafer 300 is provided, which comprises the acceptor wafer 200 and multiple two-dimensional arrays of transfer material plates 110 (which comprise patterned portions of the transfer material layers 110L). A first dielectric oxide layer (such as an acceptor-side dielectric oxide layer 220) may be located on a top surface of a handle substrate 208, and multiple two-dimensional arrays of transfer material plates 110 may be attached to the first dielectric oxide layer (such as the acceptor-side dielectric oxide layer 220) through multiple two-dimensional arrays of dielectric oxide plates 120 (which comprise patterned portions of a second dielectric oxide layer such as a donor-side dielectric oxide layer).

The two-dimensional arrays of transfer material plates 110 may be incommensurate with one another. In other words, there may not be periodicity among multiple arrays of transfer material plates 110 that are transferred from different donor wafers 100. The gap between neighboring pairs of arrays of transfer material plates 110 may be greater than the width of each intersecting channel 111′ at least by a factor of 3, and typically by a factor of 10 or more, and/or by a factor of 100 or more.

The transfer material plates 110 within each two-dimensional array of transfer material plates 110 may be laterally spaced from one another by intersecting channels 111′. The intersecting channels 111′ may vertically extend from planar top surfaces of the transfer material plates 110 to a top surface of the first dielectric oxide layer (such as the acceptor-side dielectric oxide layer 220). The height of each intersecting channel 111′ may be the same as the thickness of the transfer material plates 110, or may be the same as the sum of the thickness of the transfer material plates 110 and the thickness of the dielectric oxide plates 120.

In one embodiment, the sidewalls of the transfer material plates 110 may have a reverse-tapered profile such that the lateral extent of each transfer material plate 110 increases with a vertical distance from the first dielectric oxide layer (such as the acceptor-side dielectric oxide layer 220). In some embodiments, the sidewalls of the transfer material plates 110 may have a taper angle α as illustrated in FIG. 1G or in FIG. 3G. In one embodiment, the sidewalls of the dielectric oxide plates 120 may have a reverse-tapered profile such that the lateral extent of each dielectric oxide plate 120 increases with a vertical distance from the first dielectric oxide layer (such as the acceptor-side dielectric oxide layer 220). The sidewalls of the dielectric oxide plates 120 may have the taper angle α. In one embodiment, each of the intersecting channels 111′ may have a variable lateral width that decreases with a vertical distance upward from the top surface of the first dielectric oxide layer (such as the acceptor-side dielectric oxide layer 220).

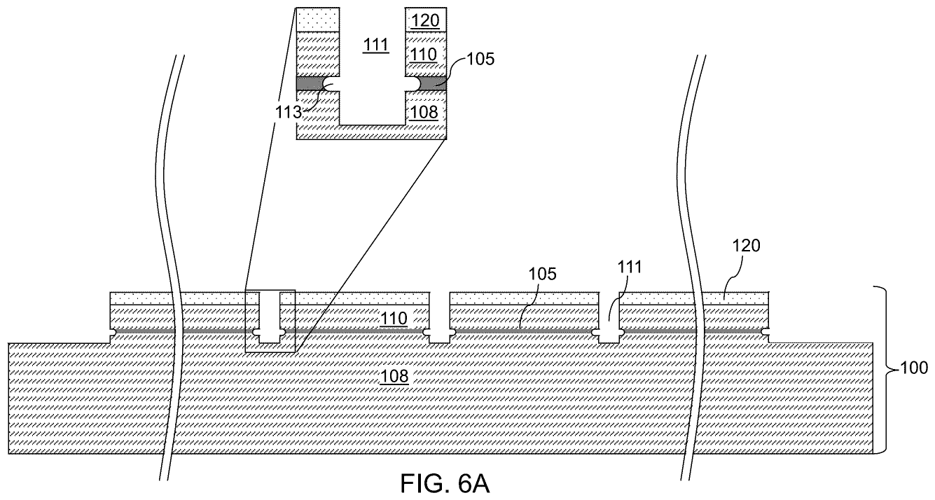

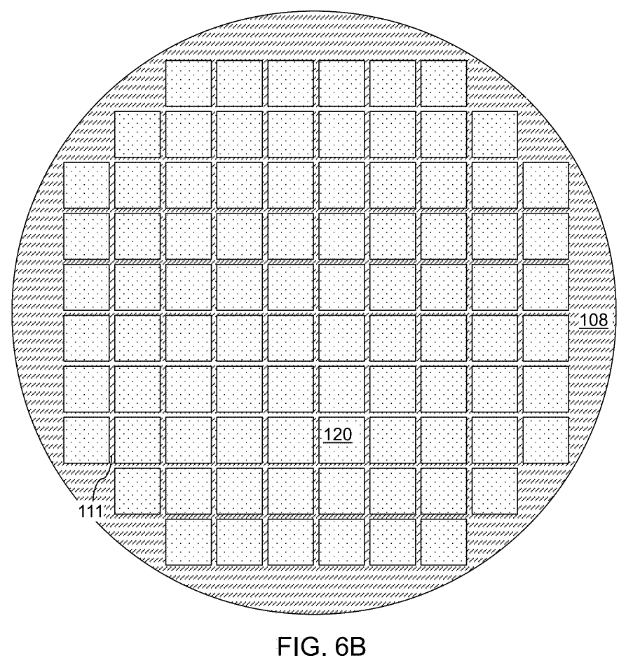

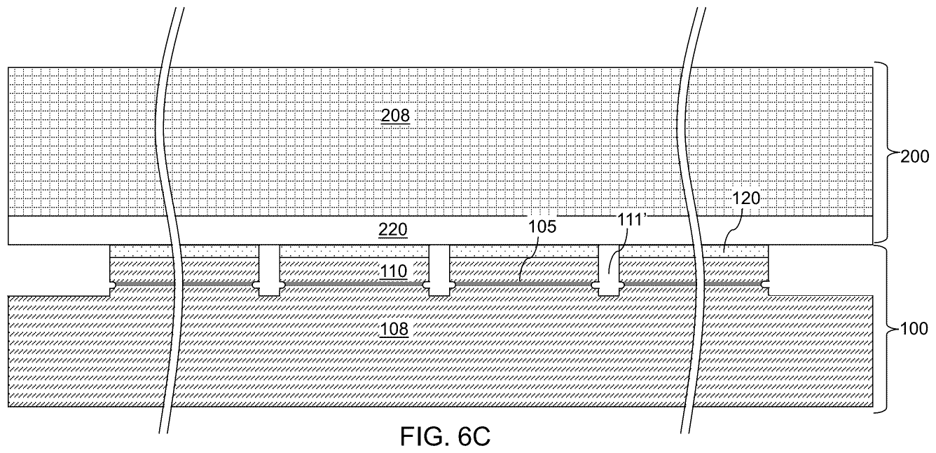

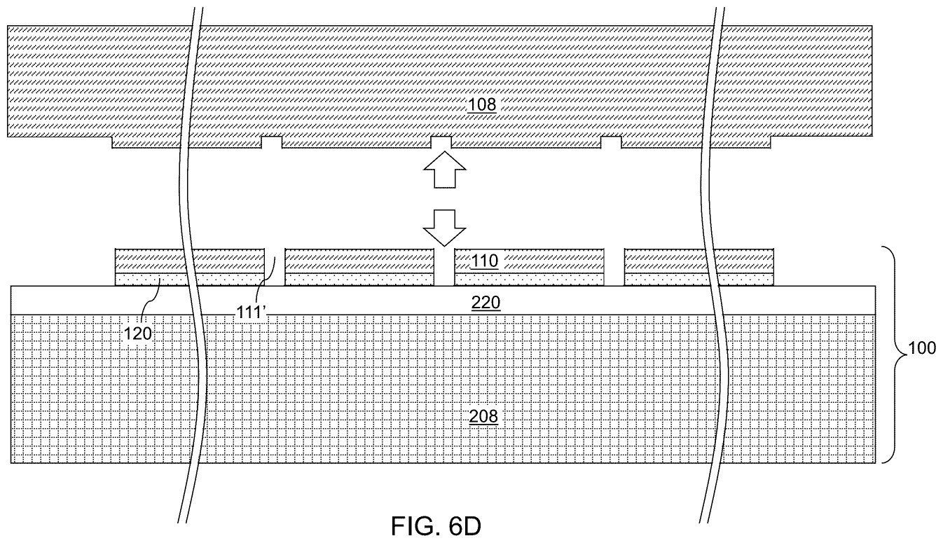

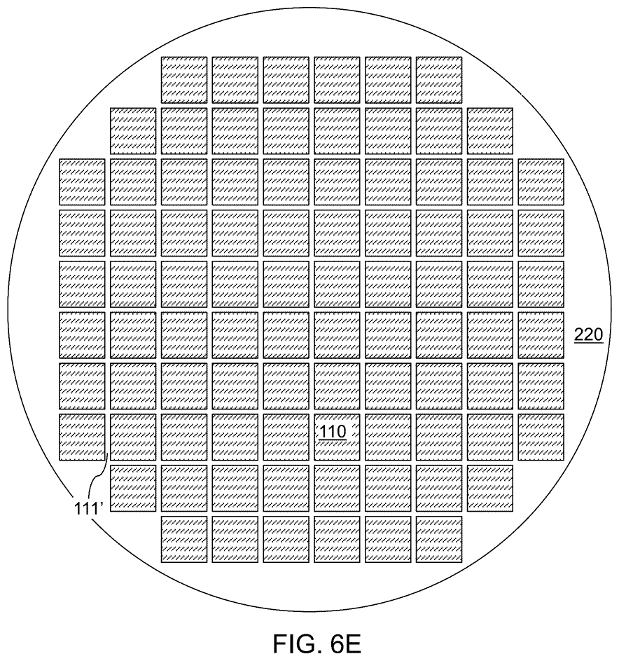

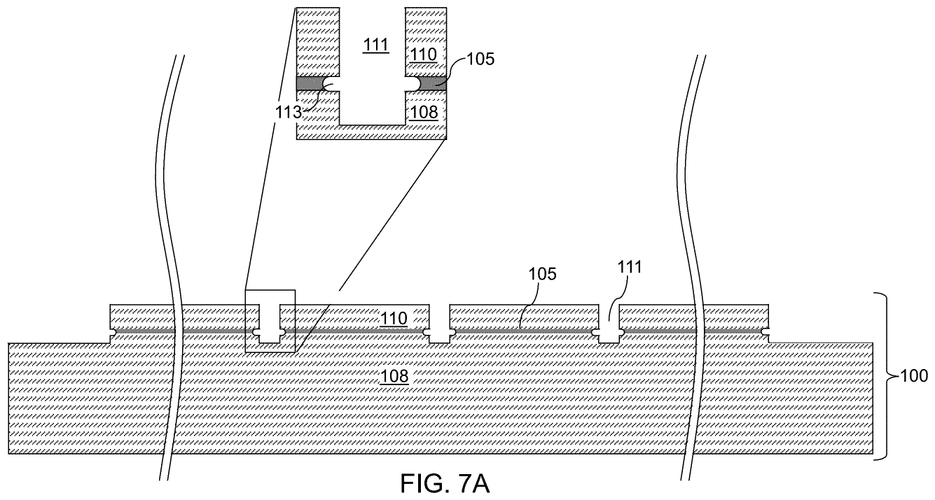

FIGS. 6A, 6C, and 6D are sequential vertical cross-sectional views of a sixth embodiment structure during formation of a composite wafer 300 according to an embodiment of the present disclosure. FIG. 6B is a top-down view of the donor wafer 100 of FIG. 6A. FIG. 6E is a top-down view of the composite wafer 300 of FIG. 6D.

Referring to FIGS. 6A and 6B, a donor wafer 100 for the sixth embodiment structure is illustrated, which may be derived from any of the donor wafers 100 illustrated in FIG. 3D, 4B, and 5B by removing a peripheral region of the layer stack (optional 120, 110, 105, 108) that is located outside areas of the patterned portions of the transfer material layer 110L (i.e., the transfer material plates 110). In one embodiment, each of the transfer material plates 110 may have a respective rectangular horizontal cross-sectional shape, and peripheral region of the layer stack (optional 120, 110, 105, 108) that may not accommodate the area of a full-sized rectangular transfer material plate 110 may be removed to provide a field region from which all material portions are removed from above a horizontal plane including bottom surfaces of the intersecting trenches 111. Generally, the peripheral region may continuously extend along the edge of the donor wafer 100 and laterally surround a two-dimensional periodic array of transfer material plates 110, and may have a variable lateral width that varies along the azimuthal angle α round a vertical axis passing through a geometrical center of the donor wafer 100. In one embodiment, the minimum of the variable lateral width may be at least twice the width of the intersecting trenches 111.

Referring to FIG. 6C, the processing steps described with reference to FIGS. 3E and 3F, or FIGS. 5B and 5C may be performed to bond each donor wafer 100 to an acceptor wafer 200. A continuous gap may be present between the first dielectric oxide layer (such as an acceptor-side dielectric oxide layer 220) of the acceptor wafer 200 and the recessed surface of the carrier layer 108 of each donor wafer 100 upon formation of a bonded assembly of the acceptor wafer 200 and each donor wafer 100.

Referring to FIGS. 6D and 6E, the processing steps described with reference to FIG. 3G, FIG. 4C, or FIGS. 5D and 5E may be performed to cleave a composite wafer 300 off the carrier layer 108. The composite wafer 300 comprises am assembly of a handle substrate 208, a first dielectric oxide layer (such as an acceptor-side dielectric oxide layer 220), at least one optional two-dimensional array of dielectric oxide plates 120, and at least one optional two-dimensional array of transfer material plates 110. In one embodiment, a peripheral region that is free of any material of the transfer material plates 110 may be present over the top surface of the first dielectric oxide layer (such as an acceptor-side dielectric oxide layer 220) around the two-dimensional array of transfer material plates 110. In one embodiment, a lateral width of the peripheral region may be greater than twice a width of each of the intersecting channels 111′.

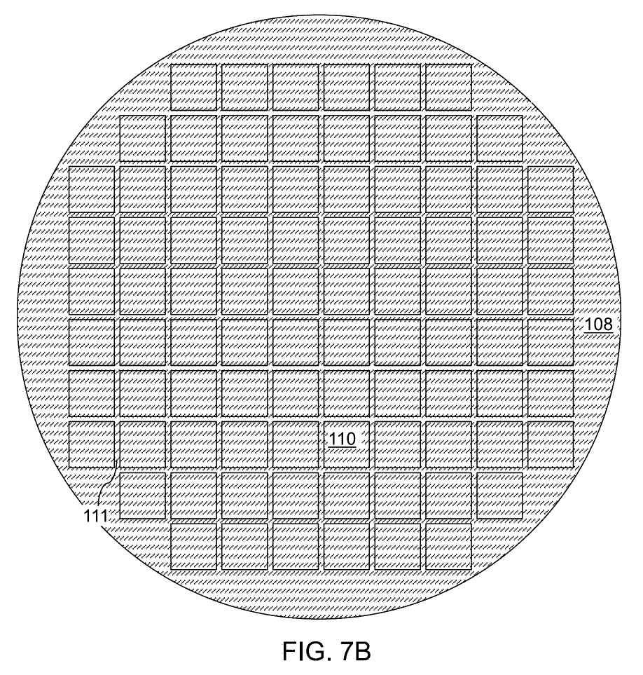

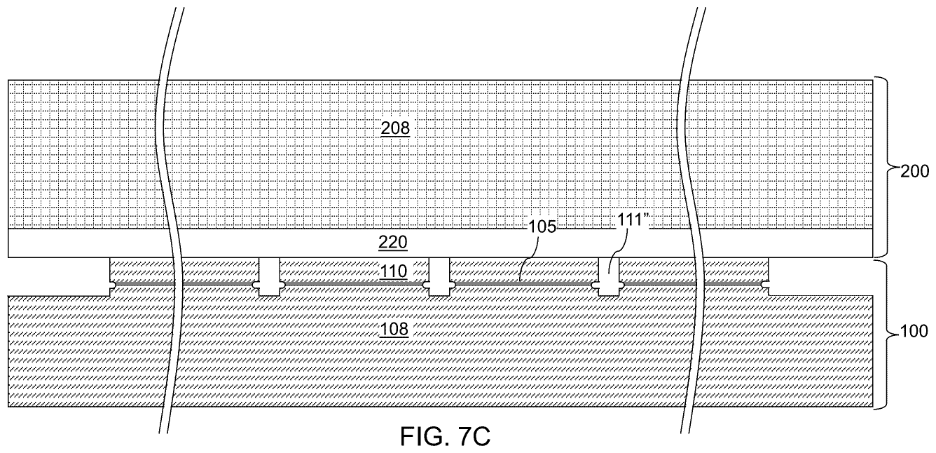

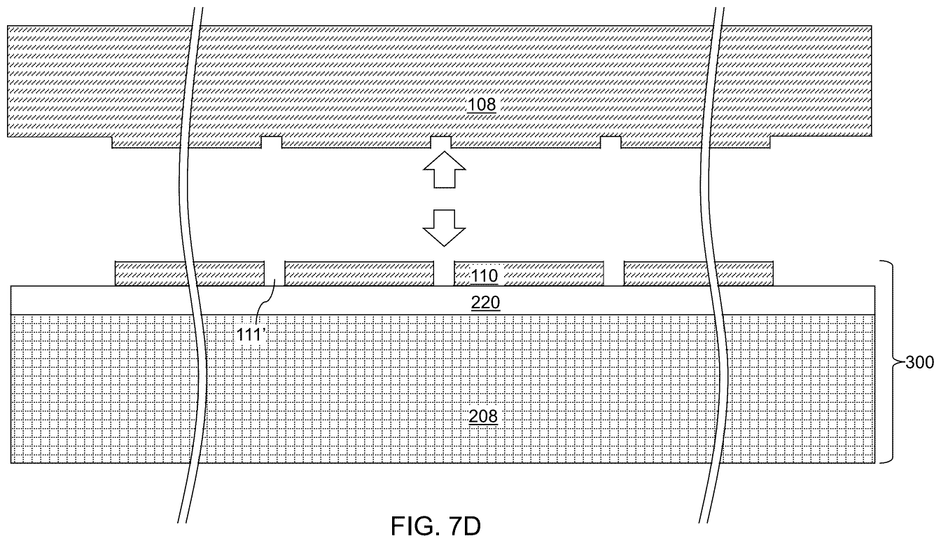

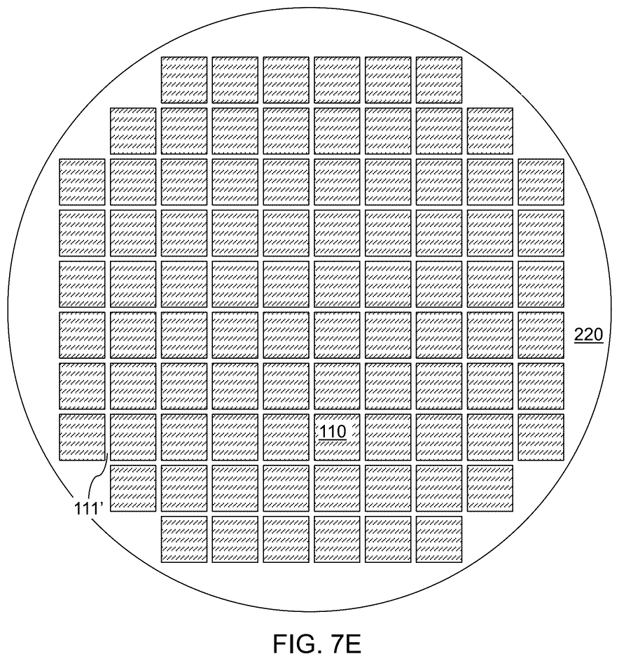

FIGS. 7A, 7C, and 7D are sequential vertical cross-sectional views of a seventh embodiment structure during formation of a composite wafer 300 according to an embodiment of the present disclosure. FIG. 7B is a top-down view of the donor wafer 100 of FIG. 7A. FIG. 7E is a top-down view of the composite wafer 300 of FIG. 7D.

Referring to FIGS. 7A and 7B, a donor wafer 100 for the seventh embodiment structure is illustrated, which may be derived from any of the donor wafers 100 illustrated in FIG. 1D, 2B, and 5B by removing a peripheral region of the layer stack (optional 120, 110, 105, 108) that is located outside areas of the patterned portions of the transfer material layer 110L (i.e., the transfer material plates 110). In one embodiment, each of the transfer material plates 110 may have a respective rectangular horizontal cross-sectional shape, and peripheral region of the layer stack (optional 120, 110, 105, 108) that may not accommodate the area of a full-sized rectangular transfer material plate 110 may be removed to provide a field region from which all material portions are removed from above a horizontal plane including bottom surfaces of the intersecting trenches 111. Generally, the peripheral region may continuously extend along the edge of the donor wafer 100 and laterally surround a two-dimensional periodic array of transfer material plates 110, and may have a variable lateral width that varies along the azimuthal angle α round a vertical axis passing through a geometrical center of the donor wafer 100. In one embodiment, the minimum of the variable lateral width may be at least twice the width of the intersecting trenches 111.

Referring to FIG. 7C, the processing steps described with reference to FIGS. 1E and 1F, or FIGS. 5B and 5C may be performed to bond each donor wafer 100 to an acceptor wafer 200. A continuous gap may be present between the first dielectric oxide layer (such as an acceptor-side dielectric oxide layer 220) of the acceptor wafer 200 and the recessed surface of the carrier layer 108 of each donor wafer 100 upon formation of a bonded assembly of the acceptor wafer 200 and each donor wafer 100.

Referring to FIGS. 7D and 7E, the processing steps described with reference to FIGS. 1G and 1H, FIG. 2C, or FIGS. 5D and 5E may be performed to cleave a composite wafer 300 off the carrier layer 108. The composite wafer 300 comprises am assembly of a handle substrate 208, a first dielectric oxide layer (such as an acceptor-side dielectric oxide layer 220), at least one optional two-dimensional array of dielectric oxide plates 120, and at least one optional two-dimensional array of transfer material plates 110. In one embodiment, a peripheral region that is free of any material of the transfer material plates 110 may be present over the top surface of the first dielectric oxide layer (such as an acceptor-side dielectric oxide layer 220) around the two-dimensional array of transfer material plates 110. In one embodiment, a lateral width of the peripheral region may be greater than twice a width of each of the intersecting channels 111′.

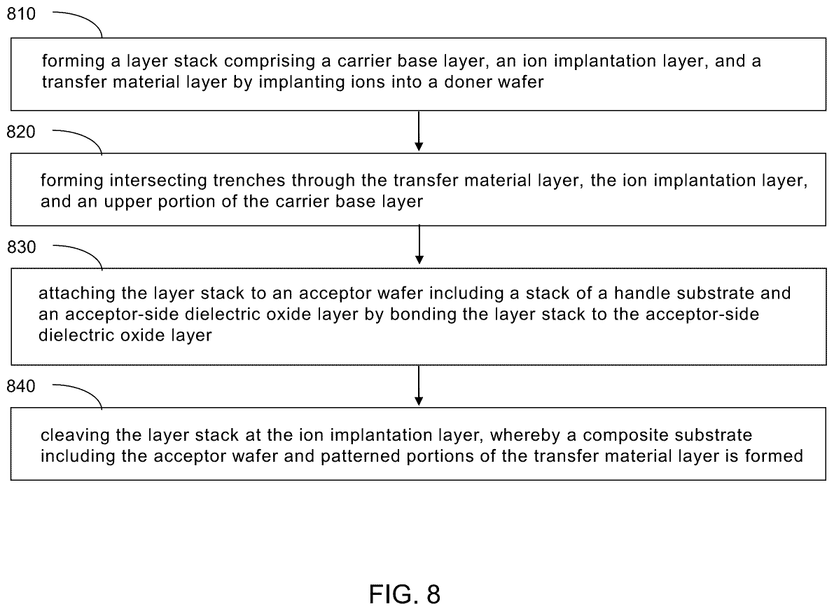

Referring to FIG. 8, a first flow chart illustrates a sequence of processing steps that may be used to form a composite wafer 300 according to an embodiment of the present disclosure.

Referring to step 810 and FIGS. 1A, 1B, 2A, 3A, 3B, 4A, 5A, 6A and 6B, and 7A and 7B, a layer stack (optional 120L, 110L, 105, 108) comprising a carrier layer 108, an ion implantation layer 105, and a transfer material layer 110L may be formed by implanting ions into a donor wafer 100.

Referring to step 820 and FIGS. 1C, 1D, 2A, 2B, 3C, 3D, 4A, 4B, 5A, 6A and 6B, and 7A and 7B, intersecting trenches 111 may be formed through the transfer material layer 110L, the ion implantation layer 105, and an upper portion of the carrier layer 108.

Referring to step 830 and FIGS. 1E and 1F, 2C, 3E and 3F, 4C, 5B and 5C, 6C, and 7C, the layer stack (optional 120, 110, 105, 108) may be attached to an acceptor wafer 200 including a stack of a handle substrate 208 and a first dielectric oxide layer (such as an acceptor-side dielectric oxide layer 220) by bonding the layer stack (optional 120, 110, 105, 108) to the first dielectric oxide layer.

Referring to step 840 and FIGS. 1G and 1H, 2C, 3G, 4C, 5D and 5E, 6D and 6E, and 7D and 7E, the layer stack (optional 120, 110, 105, 108) may be cleaved at the ion implantation layer 105, whereby a composite wafer 300 including the acceptor wafer 200 and patterned portions of the transfer material layer 110L (such as a two-dimensional array of transfer material plates 110) is formed.

In one embodiment, the method may further include the step of forming a patterned etch mask layer including intersecting laterally-extending openings over the transfer material layer 110L; and forming the intersecting trenches 111 by transferring a pattern of the intersecting laterally-extending openings into the transfer material layer 110L by performing an anisotropic etch process. In one embodiment, the intersecting trenches 111 may be formed by mechanically cutting the transfer material layer 110L, the ion implantation layer 105, and the upper portion of the carrier layer 108. In one embodiment, the method may further include forming lateral divots 113 around the intersecting trenches 111 by laterally recessing the ion implantation layer 105 selective to a material of the carrier layer 108 and the transfer material layer 110L. In one embodiment, the layer stack (110L, 105, 108) may include a second dielectric oxide layer 120L that is formed on a top surface of the transfer material layer 110L; and the method may include patterning the second dielectric oxide layer 120L into dielectric oxide plates during formation of the intersecting trenches 111. In one embodiment, the first dielectric oxide layer 220 may be bonded to the dielectric oxide plates 110 by dielectric-to-dielectric bonding. In one embodiment, the first dielectric oxide layer 220 may be bonded to the patterned portions of the transfer material layer 110L. In one embodiment, the method may also include the step of forming at least one additional layer stack comprising a respective additional carrier layer 108, a respective additional ion implantation layer 105, and a respective additional transfer material layer 110L; forming additional intersecting trenches 111 through an upper portion of each of the at least one additional layer stack; attaching the at least one additional layer stack to the acceptor wafer 200 by bonding each of the at least one additional layer stack to the first dielectric oxide layer 220; and cleaving each of the at least one additional layer stack at the respective additional ion implantation layer 105. In one embodiment, the method may further include the step of removing a peripheral region of the layer stack that is located outside areas of the patterned portions of the transfer material layer, wherein the peripheral region has a width that is at least twice a width of the intersecting trenches 111. In one embodiment, the donor wafer 100 may include a single crystalline lithium niobate wafer or a single crystalline lithium tantalate wafer.

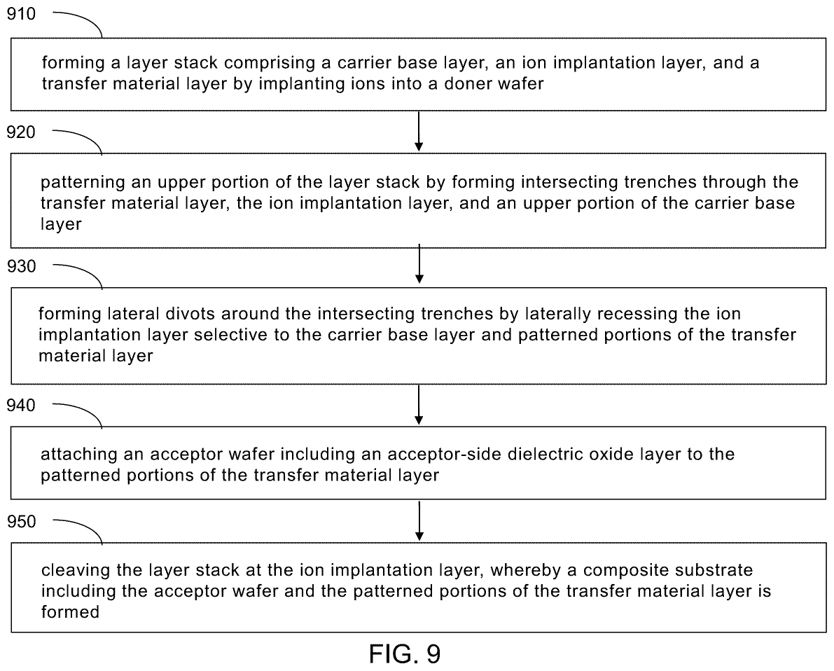

Referring to FIG. 9, a second flow chart illustrates a sequence of processing steps that may be used to form a composite wafer 300 according to an embodiment of the present disclosure.

Referring to step 910 and FIGS. 1A, 1B, 2A, 3A, 3B, 4A, 5A, 6A and 6B, and 7A and 7B, a layer stack (optional 120L, 110L, 105, 108) comprising a carrier layer 108, an ion implantation layer 105, and a transfer material layer 110L may be formed by implanting ions into a donor wafer 100.

Referring to step 920 and FIGS. 1C, 2A, 3C, 4A, 5A, 6A and 6B, and 7A and 7B, intersecting trenches 111 may be formed through the transfer material layer 110L, the ion implantation layer 105, and an upper portion of the carrier layer 108.

Referring to step 930 and FIGS. 1D, 2B, 3D, 4B, 5A, 6A and 6B, and 7A and 7B, lateral divots 113 may be formed around the intersecting trenches 111 by laterally recessing the ion implantation layer 105 selective to a material of the carrier layer 108 and patterned portions of the transfer material layer 110L (i.e., the two-dimensional array of transfer material plates 110).

Referring to step 940 and FIGS. 1E and 1F, 2C, 3E and 3F, 4C, 5B and 5C, 6C, and 7C, an acceptor wafer 200 including a first dielectric oxide layer (such as an acceptor-side dielectric oxide layer 220) may be attached to the patterned portions of the transfer material layer 110L (such as the two-dimensional array of transfer material plates 110).

Referring to step 950 and FIGS. 1G and 1H, 2C, 3G, 4C, 5D and 5E, 6D and 6E, and 7D and 7E, the layer stack (optional 120, 110, 105, 108) may be cleaved at the ion implantation layer 105, whereby a composite wafer 300 including the acceptor wafer 200 and the patterned portions of the transfer material layer 110L (such as a two-dimensional array of transfer material plates 110) is formed.

In one embodiment, intersecting laterally-extending channels 111 are formed upon attaching the acceptor wafer 200 to the patterned portions of the transfer material layer 110; and surface segments of the first dielectric oxide layer 220 are exposed to the intersecting laterally-extending channels 111. In one embodiment, intersecting laterally-extending channels 111 may be formed upon attaching the acceptor wafer 200 to the patterned portions of the transfer material layer 110; and surface segments of the first dielectric oxide layer 220 may be exposed to the intersecting laterally-extending channels 111. In one embodiment, the method may also include the steps of forming a second dielectric oxide layer 120 a top surface of the donor wafer 100; and patterning the second dielectric oxide layer 120 into dielectric oxide plates during formation of the intersecting trenches 111. In one embodiment, the second dielectric oxide layer 120 may be formed after implanting the ions into the donor wafer 100; and the dielectric oxide plates 110 are bonded to the first dielectric oxide layer 220 by dielectric-to-dielectric bonding. In one embodiment, sidewalls of the intersecting trenches 111 may be formed with a taper angle α with respect to a vertical direction such that a width of the intersecting trenches 111 decreases with a vertical distance downward from a horizontal plane including top surfaces of the patterned portions of the transfer material layer 110.

Referring to all drawings and according to various embodiments of the present disclosure, a composite wafer 300 is provided, which comprises: a first dielectric oxide layer (such as an acceptor-side dielectric oxide layer 220) located on a top surface of a handle substrate 208; and a two-dimensional array of transfer material plates 110 attached to the first dielectric oxide layer (such as an acceptor-side dielectric oxide layer 220), laterally spaced from one another by intersecting channels 111′ that vertically extend from planar top surfaces of the transfer material plates 110 to a top surface of the first dielectric oxide layer (such as an acceptor-side dielectric oxide layer 220).

In one embodiment, each of the intersecting channels 111′ have a variable lateral width that decreases with a vertical distance upward from the top surface of the first dielectric oxide layer (such as an acceptor-side dielectric oxide layer 220). In one embodiment, the composite wafer 300 comprises a two-dimensional array of dielectric oxide plates (such as dielectric oxide plates 120) interposed between the two-dimensional array of transfer material plates 110 and the first dielectric oxide layer (such as an acceptor-side dielectric oxide layer 220).

In one embodiment, the two-dimensional array of transfer material plates 110 is in contact with the top surface of the first dielectric oxide layer (such as an acceptor-side dielectric oxide layer 220). In one embodiment, a peripheral region that is free of any material of the transfer material plates 110 is present over the top surface of the first dielectric oxide layer (such as an acceptor-side dielectric oxide layer 220) around the two-dimensional array of transfer material plates 110; and a lateral width of the peripheral region is greater than twice a width of each of the intersecting channels 111′.

In one embodiment, the first dielectric oxide layer (such as an acceptor-side dielectric oxide layer 220) is bonded to the dielectric oxide plates 120 by dielectric-to-dielectric bonding. In one embodiment, the first dielectric oxide layer (such as an acceptor-side dielectric oxide layer 220) is bonded to the patterned portions of the transfer material layer 110L (i.e., the transfer material plates 110).

In one embodiment, the composite wafer 300 comprises at least one additional array of transfer material plates 110 that is transferred from at least one additional donor wafer 100.

In one embodiment, a peripheral region of a layer stack (optional 120L, 110, 105, 108) that is located outside areas of the patterned portions of the transfer material layer 110L (i.e., the transfer material plates 110) may be removed prior to transfer of the patterned portions of the transfer material layer 110L. The peripheral region has a width that is at least twice a width of the intersecting trenches 111.

In one embodiment, the donor wafer 100 comprises a single crystalline lithium niobate wafer or a single crystalline lithium tantalate wafer, and the composite wafer 300 comprises at least one two-dimensional array of single crystalline lithium niobate material plates having a same crystallographic orientation, or at least one two-dimensional array of single crystalline lithium tantalate material plates having a same crystallographic orientation.

In one embodiment, sidewalls of the intersecting trenches 111 may be formed with a taper angle α with respect to a vertical direction such that a width of the intersecting trenches 111 decreases with a vertical distance downward from a horizontal plane including top surfaces of the patterned portions of the transfer material layer 110L (i.e., the transfer material plates 110). In this embodiment, the intersecting channels 111′ may be formed with reverse-tapered sidewalls having the taper angle α such that the width of each channel selected from the intersecting channels 111′ has a variable width that decreases with a vertical distance from a top surface of the first dielectric oxide layer (such as the acceptor-side dielectric oxide layer 220).

The various embodiments of the present disclosure may be used to provide a composite wafer 300 including at least one two-dimensional array of transfer material plates 110. The transfer material plates 110 may have a coefficient of thermal expansion which has a large mismatch relative to the coefficient of thermal expansion of the material of the handle substrate 208. In an illustrative example, the handle substrate 208 may comprise single crystalline silicon having a coefficient of thermal expansion of about 2.6×10⁻⁶/° C. at a temperature of 20° C., and the transfer material plates 110 may comprise lithium niobate (LiNbO₃) having a coefficient of thermal expansion of about 4.0×10⁻⁶/° C. along directions that are perpendicular to the axial direction (c-direction) at a temperature of 20° C. and having a coefficient of thermal expansion of about 1.5×10⁻⁵/° C. along the axial direction (c-direction) at a temperature of 20° C. In another illustrative example, the handle substrate 208 may comprise single crystalline silicon having a coefficient of thermal expansion of about 2.6×10⁻⁶/° C. at a temperature of 20° C., and the transfer material plates 110 may comprise single crystalline indium gallium zinc oxide having a coefficient of thermal expansion of about 7.2×10⁻⁶/° C. at a temperature of 20° C. The lateral dimensions of each of the transfer material plates 110 may be limited, and may be in a range from 1% to 50% of the lateral dimension of the handle substrate 208. Thus, the limited lateral dimension of the transfer material plates 110 may limit thermal expansion of the transfer material plates 110 during the bonding process to prevent cracking of the composite wafer 300. In addition, limiting the lateral dimension of the transfer material plates 110, the intersecting trenches 111 may provide some flexibility to the bonded layer stack to also mitigate against warpage and cracking. Thus, a high quality composite wafer 300 that is free of cracking or having a low density of cracking defects may be provided even for transfer materials having a large mismatch in the coefficient of thermal expansion relative to the material of the handle substrate 208.

The foregoing outlines features of several embodiments so that those skilled in the art may better understand the aspects of the present disclosure. Each embodiment described employing the term “comprises” also inherently discloses that the term “comprises” can be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements can be also impliedly disclosed in some embodiments. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a composite wafer, comprising:
forming a layer stack comprising a carrier layer, an ion implantation layer, and a transfer material layer by implanting ions into a donor wafer;
forming trenches through the transfer material layer, the ion implantation layer, and an upper portion of the carrier layer;
attaching the layer stack to an acceptor wafer including a stack of a handle substrate and a first dielectric oxide layer by bonding the layer stack to the first dielectric oxide layer; and
cleaving the layer stack at the ion implantation layer, whereby a composite wafer including the acceptor wafer and patterned portions of the transfer material layer is formed.

2. The method of claim 1, further comprising:
forming a patterned etch mask layer including intersecting laterally-extending openings over the transfer material layer; and
forming the trenches by transferring a pattern of the intersecting laterally-extending openings into the transfer material layer by performing an anisotropic etch process.

3. The method of claim 1, wherein the trenches are formed by mechanically cutting the transfer material layer, the ion implantation layer, and the upper portion of the carrier layer.

4. The method of claim 1, further comprising forming lateral divots around the trenches by laterally recessing the ion implantation layer selective to a material of the carrier layer and the transfer material layer.

5. The method of claim 1, wherein:
the layer stack comprises a second dielectric oxide layer that is formed on a top surface of the transfer material layer; and
the method comprises patterning the second dielectric oxide layer into dielectric oxide plates during formation of the trenches.

6. The method of claim 5, wherein the first dielectric oxide layer is bonded to the dielectric oxide plates by dielectric-to-dielectric bonding.

7. The method of claim 1, wherein the first dielectric oxide layer is bonded to the patterned portions of the transfer material layer.

8. The method of claim 1, further comprising:
forming at least one additional layer stack comprising a respective additional carrier layer, a respective additional ion implantation layer, and a respective additional transfer material layer;
forming additional trenches through an upper portion of each of the at least one additional layer stack;
attaching the at least one additional layer stack to the acceptor wafer by bonding each of the at least one additional layer stack to the first dielectric oxide layer; and
cleaving each of the at least one additional layer stack at the respective additional ion implantation layer.

9. The method of claim 1, further comprising removing a peripheral region of the layer stack that is located outside areas of the patterned portions of the transfer material layer, wherein the peripheral region has a width that is at least twice a width of the trenches.

10. The method of claim 1, wherein the donor wafer comprises a single crystalline lithium niobate wafer or a single crystalline lithium tantalate wafer.

11. A method of forming a composite wafer, the method comprising:
forming a layer stack comprising a carrier layer, an ion implantation layer, and a transfer material layer by implanting ions into a donor wafer;
patterning an upper portion of the layer stack by forming trenches through the transfer material layer, the ion implantation layer, and an upper portion of the carrier layer;
forming lateral divots around the trenches by laterally recessing the ion implantation layer selective to a material of the carrier layer and patterned portions of the transfer material layer;
attaching an acceptor wafer including a first dielectric oxide layer to the patterned portions of the transfer material layer; and
cleaving the layer stack at the ion implantation layer, whereby a composite wafer including the acceptor wafer and the patterned portions of the transfer material layer is formed.

12. The method of claim 11, wherein:
intersecting laterally-extending channels are formed upon attaching the acceptor wafer to the patterned portions of the transfer material layer; and
surface segments of the first dielectric oxide layer are exposed to the intersecting laterally-extending channels.

13. The method of claim 11, further comprising:
forming a second dielectric oxide layer a top surface of the donor wafer; and
patterning the second dielectric oxide layer into dielectric oxide plates during formation of the trenches.

14. The method of claim 13, wherein:
the second dielectric oxide layer is formed after implanting the ions into the donor wafer; and
the dielectric oxide plates are bonded to the first dielectric oxide layer by dielectric-to-dielectric bonding.

15. The method of claim 11, wherein sidewalls of the trenches are formed with a taper angle with respect to a vertical direction such that a width of the trenches decreases with a vertical distance downward from a horizontal plane including top surfaces of the patterned portions of the transfer material layer.

16. A composite wafer comprising:
a first dielectric oxide layer located on a top surface of a handle substrate; and
a two-dimensional array of transfer material plates attached to the first dielectric oxide layer, laterally spaced from one another by intersecting channels that vertically extend from planar top surfaces of the transfer material plates to a top surface of the first dielectric oxide layer.

17. The composite wafer of claim 16, wherein each of the intersecting channels have a variable lateral width that decreases with a vertical distance upward from the top surface of the first dielectric oxide layer.

18. The composite wafer of claim 17, further comprising a two-dimensional array of dielectric oxide plates interposed between the two-dimensional array of transfer material plates and the first dielectric oxide layer.

19. The composite wafer of claim 17, wherein the two-dimensional array of transfer material plates is in contact with the top surface of the first dielectric oxide layer.

20. The composite wafer of claim 16, wherein:
a peripheral region that is free of any material of the transfer material plates is present over the top surface of the first dielectric oxide layer around the two-dimensional array of transfer material plates; and
a lateral width of the peripheral region is greater than twice a width of each of the intersecting channels.
